(19) United States
(12) Patent Application Publication
(10) Pub. No.: US 2010/0294650 A1
(43) Pub. Date: Nov. 25, 2010

(54) PROCESS FOR PRODUCING LIQUID CRYSTAL DISPLAY DEVICE

(75) Inventors: Hirohisa Takahashi, Sanmu-shi (JP); Satoru Ishibashi, Sanmu-shi (JP)

Correspondence Address: GROSSMAN, TUCKER, PERREAULT & PFLEGER, PLLC, 55 SOUTH COMMERICAL STREET, MANCHESTER, NH, 03101, US

(73) Assignee: ULVAC, INC., Chigasaki-shi (JP)

(21) Appl. No.: 12/864,179

(22) PCT Filed: Jan. 20, 2009
(86) PCT No.: PCT/JP2009/050781

§ 371 Date: Jul. 22, 2010

(30) Foreign Application Priority Data
Jan. 24, 2008 (JP) P2008-013680

(51) Int. Cl. C23C 14/34

(52) U.S. Cl. 204/192.17

(57) ABSTRACT

A process for producing a liquid crystal display device that includes at least a pair of substrates holding a liquid crystal layer therebetween and a pixel electrode superimposed on the liquid crystal layer side of the pair of substrates, the pixel electrode on at least one of the pair of substrates being formed of a transparent electroconductive film made of zinc oxide as a fundamental constituent material, the process includes: a step of forming a zinc oxide transparent electroconductive film on the substrate by sputtering, using a target of a zinc oxide series material to form the pixel electrode, wherein, in the step of forming the pixel electrode, sputtering is performed in an atmosphere containing two or three materials selected from the group consisting of hydrogen gas, oxygen gas, and water vapor.

### BACKGROUND OF THE PRESENT INVENTION

1. Field of the Invention

The present invention relates to a process for producing a liquid crystal display device, and more specifically, relates to a process for producing a transparent electroconductive film used as a pixel electrode of the liquid crystal display device.

Priority is claimed on Japanese Patent Application No. 2008-013680, filed on Jan. 24, 2008, the contents of which are incorporated herein by reference.

2. Background Art

Conventionally, ITO (In₂O₃—SnO₂) has been used as a material of a transparent electroconductive film that forms a pixel electrode of a liquid crystal display device (LCD). However, indium (In), which is a raw material of ITO is a rare metal, and cost increase is predicted in the future due to unavailability. Therefore, as a material of the transparent electroconductive film which replaces ITO, an abundant and inexpensive ZnO series material is attracting attention (for example, refer to Japanese Unexamined Patent Application, First Publication No. H 09-87833). The ZnO series material is suitable for sputtering capable of forming a uniform film on a large substrate. In a film formation apparatus, a film can be formed by changing a target of an In₂O₃ series material such as ITO to a target of the ZnO series material. Moreover, the ZnO series material does not include lower oxide (InO) having high insulation properties such as the In₂O₃ series material. Therefore, abnormalities are difficult to occur in sputtering.

In the transparent electroconductive film that forms the pixel electrode and uses the conventional ZnO series material, although the transparent electroconductive film has transparency that can be favorably compared with an ITO film, there is a problem in that surface resistance is high. Therefore, in order to reduce the surface resistance of the transparent electroconductive film using the ZnO series material to a desired value, a method has been proposed where hydrogen gas is introduced into a chamber as a reducing gas at the time of sputtering, and a film is formed in a reducing atmosphere.

In this case however, although the surface resistance of the obtained transparent electroconductive film certainly decreases, metallic luster is slightly generated on the surface thereof. Accordingly, there is a problem in that light transmittance decreases and visibility of the liquid crystal display device degrades.

### SUMMARY OF THE PRESENT INVENTION

The present invention has been made to solve the above problems, and has an object to provide a process for producing a liquid crystal display device in which the surface resistance of a transparent electroconductive film that forms a pixel electrode formed by using a zinc oxide series material is decreased, and transparency of visible light is maintained favorably to improve visibility.

The present invention adopts the following measures in order to solve the above problems and achieve the object.

(1) A process for producing a liquid crystal display device that includes at least a pair of substrates holding a liquid crystal layer therebetween, and a pixel electrode superimposed on the liquid crystal layer side of the pair of substrates, the pixel electrode on at least one of the pair of substrates being formed of a transparent electroconductive film made of zinc oxide as a fundamental constituent material. The production process includes a step of forming a zinc oxide transparent electroconductive film on the substrate by sputtering, using a target of a zinc oxide series material to form the pixel electrode. In the step of forming the pixel electrode, sputtering is performed in an atmosphere containing two or three materials selected from the group consisting of hydrogen gas, oxygen gas, and water vapor.

The process for producing the liquid crystal display device can be performed in the following manner.

(2) A ratio R (P_{H2}/P_{O2}) of a partial pressure of hydrogen gas (P_{H2}) to a partial pressure of oxygen gas (P_{O2}) satisfies:

R=P_{H2}/P_{O2}≧5 (1)

In the case of (2), by satisfying R=P_{H2}/P_{O2}≧5, a transparent electroconductive film having a specific resistance that is less than or equal to 1000 nΩ·cm can be obtained.

(3) A sputtering voltage is less than or equal to 340V.

In the case of (3), a zinc oxide transparent electroconductive film in which crystal lattices are aligned can be formed by dropping the discharge voltage. Therefore, the specific resistance of the obtained transparent electroconductive film becomes low.

(4) In the sputtering voltage, a high-frequency voltage is superimposed on a direct-current voltage.

In the case of (4), the discharge voltage can be further dropped by superimposing the high-frequency voltage on the direct-current voltage.

(5) A maximum value of the intensity of a horizontal magnetic field on a surface of the target is greater than or equal to 600 gauss.

In the case of (5), the discharge voltage can be further dropped by setting the maximum value of the intensity of the horizontal magnetic field to be greater than or equal to 600 gauss.

(6) The liquid crystal display device further includes a color filter between the liquid crystal layer and the substrate, and the pixel electrode is formed between the color filter and the liquid crystal layer.

(7) The zinc oxide series material is aluminum doped zinc oxide or gallium doped zinc oxide.

According to the process for producing the liquid crystal display device described in (1), when the zinc oxide transparent electroconductive film that forms the pixel electrode of the liquid crystal display device is formed by sputtering, sputtering is performed in an atmosphere containing two or three materials selected from the group consisting of hydrogen gas, oxygen gas, and water vapor. Therefore, the atmosphere at the time of forming the zinc oxide transparent electroconductive film can be an atmosphere including two or three materials selected from the group consisting of hydrogen gas, oxygen gas, and water vapor, that is, an atmosphere in which a ratio of reducing gas to oxidizing gas is well-balanced. Accordingly, if sputtering is performed in this atmosphere, the obtained transparent electroconductive film becomes a film having a desired electrical conductivity, with the number of oxygen vacancies in the zinc oxide crystals being controlled. Therefore, surface resistance thereof also decreases to become a desired surface resistance value.

Moreover, the obtained transparent electroconductive film does not have a metallic luster and can maintain transparency with respect to visible light. Furthermore, transparency with respect to the visible light can be maintained.

Therefore, a zinc oxide transparent electroconductive film that forms the pixel electrode of the liquid crystal display device can be formed easily, with a low electrical resistivity and excellent transparency with respect to visible light. Accordingly, it is possible to produce a liquid crystal display device having high degree of transparency and excellent visibility with low power consumption.

### BRIEF DESCRIPTION OF THE DRAWINGS

FIG. 1 is a schematic block diagram of a film formation apparatus suitable for a process for producing a liquid crystal display device of the present invention.

FIG. 2 is a cross-sectional view of the film formation apparatus suitable for the process for producing the liquid crystal display device of the present invention.

FIG. 3 is a cross-sectional view showing another example of the film formation apparatus.

FIG. 4 is a cross-sectional view showing an example of a liquid crystal display device formed by the production process of the present invention.

FIG. 5 is a graph showing an effect of introduced gas in Example 1.

FIG. 6 is a graph showing the effect of introduced gas in Example 2.

FIG. 7 is a graph showing the effect of introduced gas in Example 3.

FIG. 8 is a graph showing the effect of introduced gas in Example 4.

FIG. 9 is a graph showing the effect of introduced gas in Example 5.

FIG. 10 is a graph showing the effect of introduced gas in Example 6.

FIG. 11 is a graph showing the effect of introduced gas in Example 7.

### DESCRIPTION OF THE PREFERRED EMBODIMENTS

A best mode for a process for producing a liquid crystal display device according to the present invention is explained with reference to the drawings. The embodiment is specifically explained for better understanding of the scope of the invention, and does not limit the present invention unless otherwise specified.

At first, in relation to the process for producing the liquid crystal display device of the present invention, an example of a sputtering apparatus (film formation apparatus) suitable for forming a zinc oxide transparent electroconductive film that forms a pixel electrode (transparent electrode) is explained.

Sputtering Apparatus 1

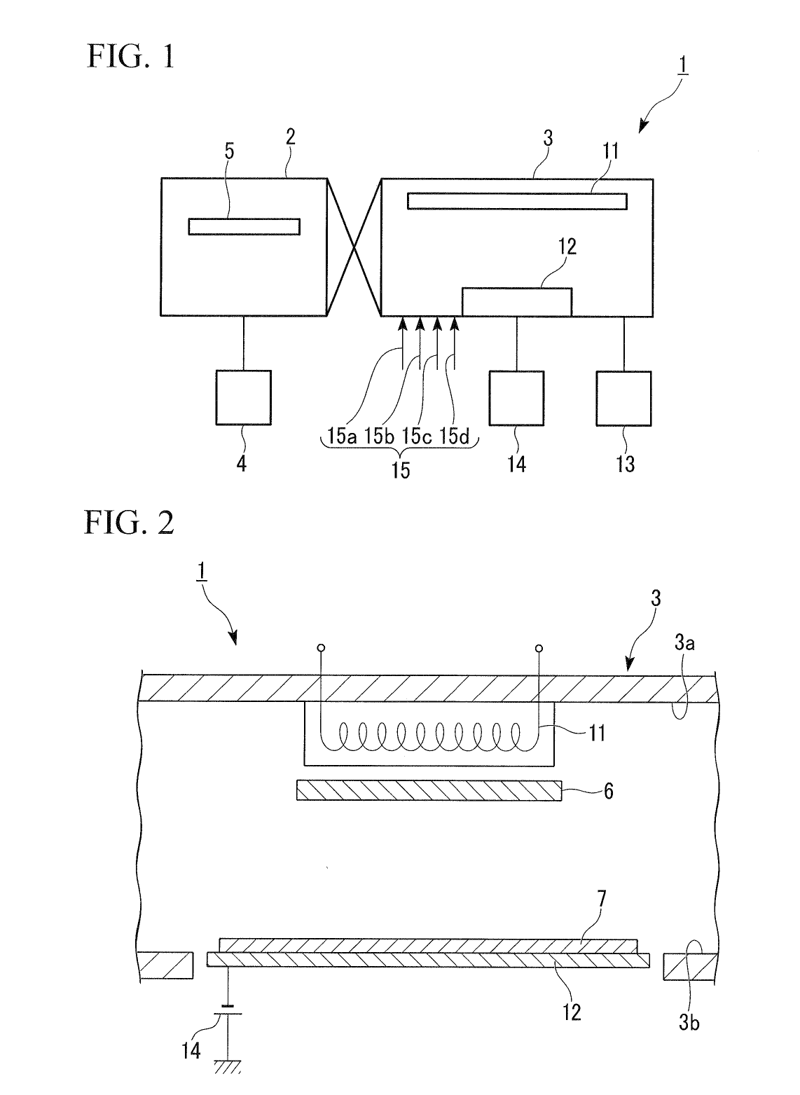

FIG. 1 is a schematic block diagram of a sputtering apparatus (film formation apparatus) according to a first embodiment. FIG. 2 is a cross-sectional view of a main part of a film formation chamber of the sputtering apparatus. A sputtering apparatus 1 is an interback-type sputtering apparatus. The sputtering apparatus 1 includes, for example, a load-unload chamber 2 that brings in or removes substrates such as an alkali-free glass substrate (not shown), and a film formation chamber 3 (vacuum container) in which a zinc oxide transparent electroconductive film is formed on the substrate.

The load-unload chamber 2 includes a roughing exhaust unit 4 such as a rotary pump that roughly evacuates the chamber. Moreover, a substrate tray 5 for holding and carrying the substrate is movably arranged in the chamber.

A heater 11 that heats a substrate 6 is vertically provided on one side 3a of the film formation chamber 3. A sputtering cathode mechanism 12 (target holding unit) that holds a target 7 of a zinc oxide series material and applies a desired sputtering voltage thereto is vertically provided on the other side 3b of the film formation chamber 3. Furthermore, a high-vacuum exhaust unit 13 such as a turbo-molecular pump that highly evacuates the film formation chamber 3, a power source 14 that applies the sputtering voltage to the target 7, and a gas introducing unit 15 that introduces gas into the film formation chamber 3 are further provided on the other side 3b.

The sputtering cathode mechanism 12 includes a plate-like metal plate. The sputtering cathode mechanism 12 fixes the target 7 by bonding (fixation) using a brazing filler metal or the like.

The power source 14 applies a sputtering voltage in which a high-frequency voltage is superimposed on a direct-current voltage, to the target 7. The power source 14 includes a direct-current power source and a high-frequency power source (not shown).

The gas introducing unit 15 includes a sputtering gas introducing unit 15a that introduces sputtering gas such as Ar, a hydrogen gas introducing unit 15b that introduces hydrogen gas, an oxygen gas introducing unit 15c that introduces oxygen gas, and a water vapor introducing unit 15d that introduces water vapor.

In the gas introducing unit 15, the hydrogen gas introducing unit 15b, the oxygen gas introducing unit 15c, and the water vapor introducing unit 15d can be selected and used according to need. For example, the gas introducing unit 15 can be formed by two units of, for example, the hydrogen gas introducing unit 15b and the oxygen gas introducing unit 15c, or the hydrogen gas introducing unit 15b and the water vapor introducing unit 15d.

Sputtering Apparatus 2

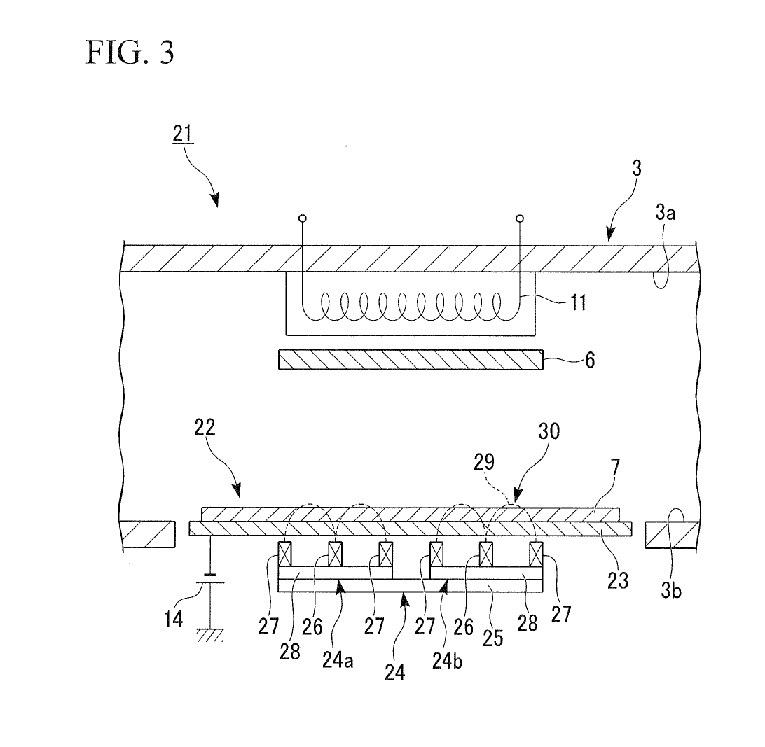

FIG. 3 is a cross-sectional view showing an example of another sputtering apparatus used for the process for producing the liquid crystal display device of the present invention, that is, a main part of a film formation chamber of an interback-type magnetron sputtering apparatus. A magnetron sputtering apparatus 21 shown in FIG. 3 is different from the sputtering apparatus 1 shown in FIGS. 1 and 2 in that a target 7 of a zinc oxide series material is held on the other side 3b of the film formation chamber 3, and a sputtering cathode mechanism 22 (target holding unit) that generates a desired magnetic field is provided vertically.

The sputtering cathode mechanism 22 includes a back plate 23 on which the target 7 is bonded (fixed) by a brazing filler metal, and a magnetic circuit 24 arranged along the back side of the back plate 23. The magnetic circuit 24 generates a horizontal magnetic field on a surface of the target 7. In the magnetic circuit 24, a plurality of magnetic circuit units 24a and 24b (two in FIG. 3) are connected and integrated by a bracket 25. Each of the magnetic circuit units 24a and 24b includes a first magnet 26 and a second magnet 27, and a yoke 28 mounting these magnets.

In the magnetic circuit 24, a magnetic field expressed by a line of magnetic force 29 is generated due to the first magnet 26 and the second magnet 27 having different polarity on the back plate 23 side. Accordingly, there is a position 30 at which the vertical magnetic field becomes 0 (the horizontal magnetic field becomes maximum) on the surface of the target 7 between the first magnet 26 and the second magnet 27. At this position 30, high-density plasma is generated. As a result, film forming speed is improved.

In the film formation apparatus shown in FIG. 3, the sputtering cathode mechanism 22 that generates the desired magnetic field, is vertically provided on the other side 3b of the film formation chamber 3. Therefore, a zinc oxide transparent electroconductive film in which crystal lattices are aligned can be formed by setting the sputtering voltage to 340V or less, and the maximum value of the horizontal field strength on the surface of the target 7 to 600 gauss or more. At this time, the maximum value of the horizontal field strength is set to 600 gauss or more in a range that can be formed by a permanent magnet. As the horizontal field strength becomes larger, a transparent electroconductive film having a smaller specific resistance can be formed. Moreover, the sputtering voltage is set to 340V or less in a range capable of performing electric discharge, although this depends on the horizontal field strength. The zinc oxide transparent electroconductive film formed under such a condition is hardly oxidized even if annealing is performed at a high temperature after the film is formed, and hence, an increase in the specific resistance can be suppressed. Therefore, the zinc oxide transparent electroconductive film that forms the pixel electrode of the liquid crystal display device can have excellent heat resistance.

Liquid Crystal Display Device

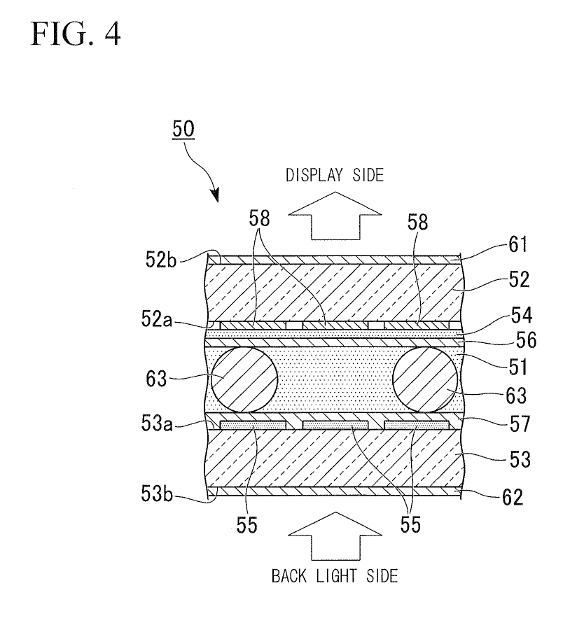

A liquid crystal display device produced according to the embodiment is explained with reference to FIG. 4. FIG. 4 is a cross-sectional view showing an example of a configuration of a transmissive liquid crystal display device. A liquid crystal display device 50 includes a pair of substrates 52 and 53 (glass substrates) holding a liquid crystal layer 51 therebetween, and pixel electrodes 54 and 55 (transparent electrodes) superimposed on one side 52a and 53a (liquid crystal layer side) of the respective substrates 52 and 53. A thin-film transistor (TFT) (not shown) is formed on the substrate 53 side, to select a pixel electrode 55 of a pixel, to which voltage is applied.

Oriented films 56 and 57 are respectively formed between the pixel electrodes 54 and 55 and the liquid crystal layer 51.

A color filter 58 is formed between the pixel electrode 54 and the substrate 52.

Polarizing plates 61 and 62 are respectively formed on the other sides 52b and 53b of the substrates 52 and 53.

A spacer 63 that maintains the liquid crystal layer 51 in a predetermined thickness is scattered on the liquid crystal layer 51.

In the liquid crystal display device 50 having such a configuration, high transparency is required for the pixel electrodes 54 and 55 in order to increase the transmittance of illumination light of a back light and improve the visibility of the liquid crystal layer 51. In addition, the pixel electrodes 54 and 55 are required to have a low resistance in order to apply a predetermined voltage to the liquid crystal layer 51 with low power consumption.

In order to obtain both high transparency and high electrical conductivity (low resistance), the pixel electrodes 54 and 55 (transparent electrodes) of the liquid crystal display device 50 in the embodiment are formed of a zinc oxide film (transparent electroconductive film) formed by using the sputtering apparatus 1 shown in FIGS. 1 and 2.

At the time of forming the film of the pixel electrodes 54 and 55, sputtering is performed in an atmosphere containing two or three materials selected from the group consisting of hydrogen gas, oxygen gas, and water vapor, by using the sputtering apparatus. As a result, a transparent electroconductive film having, particularly, a low specific resistance and high optical transparency in the visible light range, among the zinc oxide films can be obtained. Accordingly, a liquid crystal display device 50 having pixel electrodes 54 and 55 (transparent electrodes) with high transparency, excellent visibility, and low-value resistance can be realized.

Of the pixel electrodes 54 and 55 (transparent electrodes), only one of the pixel electrodes need be formed of the zinc oxide film and the other pixel electrode can be formed of an ITO film or the like. Moreover, to reduce cost, the pair of substrates 52 and 53 can be formed by using alkali glass, and a silicon oxide thin film can be provided as a sodium barrier layer of the alkali glass between the pixel electrode 54 (transparent electrode) and the color filter 58. Such a silicon oxide thin film can also function as an etching stopper at the time of etching.

Process for Producing the Liquid Crystal Display Device

As an example of a process for producing the liquid crystal display device, a method for forming a zinc oxide transparent electroconductive film that forms a pixel electrode of the liquid crystal display device on a substrate by using the sputtering apparatus 1 shown in FIGS. 1 and 2, is exemplified.

Al-doped ZnO (AZO) films (54 and 55) are formed on substrates (glass substrates) 6 (52 and 53) of the liquid crystal display device.

At first, the target 7 is fixed to the sputtering cathode mechanism 12 by bonding using a brazing filler metal. As a target material, there can be mentioned a zinc oxide series material, for example, aluminum doped zinc oxide (AZO) in which aluminum (Al) is doped by 0.1 to 10% by mass, or gallium doped zinc oxide (GZO) in which gallium (Ga) is doped by 0.1 to 10% by mass. Among these, aluminum doped zinc oxide (AZO) is preferable from the standpoint that a thin film having low specific resistance can be formed.

The load-unload chamber 2 and the film formation chamber 3 are roughly evacuated by the roughing exhaust unit 4, in a state where the substrate (glass substrate) 6 (52 and 53) of the liquid crystal display device, for example, formed of glass, is housed in a substrate tray 5 in the load-unload chamber 2. After the load-unload chamber 2 and the film formation chamber 3 become a predetermined degree of vacuum, for example, 0.27 Pa (2.0×10⁻³ Torr), the substrate 6 (52 and 53) is carried from the load-unload chamber 2 into the film formation chamber 3. Then, the substrate 6 (52 and 53) is arranged in front of the heater 11 in a state being set to OFF, so that the substrate 6 faces the target 7, and the substrate 6 is heated by the heater 11. The temperature of the substrate 6 (52 and 53) is set within a temperature range of 100° C. to 600° C.

Then, the film formation chamber 3 is highly evacuated by the high-vacuum exhaust unit 13. After the film formation chamber 3 becomes a high degree of vacuum, for example, 2.7×10⁻⁴ Pa (2.0×10⁻⁶ Torr), sputtering gas such as Ar is introduced to the film formation chamber 3 by the sputtering gas introducing unit 15a. Furthermore, two or three kinds of gas selected from the group consisting of hydrogen gas, oxygen gas, and water vapor are introduced by using two or three units of; the hydrogen gas introducing unit 15b, the oxygen gas introducing unit 15c, and the water vapor introducing unit 15d.

Here, when hydrogen gas and oxygen gas are selected, it is preferable that the ratio R (P_{H2}/P_{O2}) of the partial pressure of hydrogen gas (P_{H2}) to the partial pressure of oxygen gas (P_{O2}) satisfy:

R=P_{H2}/P_{O2}≧5 (2)

Accordingly, the atmosphere in the film formation chamber 3 becomes a reactive gas atmosphere in which the concentration of hydrogen gas is five times the concentration of oxygen gas. By satisfying R=P_{H2}/P_{O2}≧5, a transparent electroconductive film having a specific resistance of 1000 μΩ·cm or less can be obtained. It is preferable that the pixel electrode (transparent electrode) of the liquid crystal display device have a specific resistance of 1000 μΩ·cm or less.

Next, a sputtering voltage in which, for example, a high-frequency voltage is superimposed on a direct-current voltage, is applied to the target 7 by the power source 14. Due to application of the sputtering voltage, plasma is generated on the substrate 6. Sputtering gas ions such as Ar excited by the plasma collide with the target 7, so that atoms constituting the zinc oxide series material such as aluminum doped zinc oxide (AZO) or gallium doped zinc oxide (GZO) fly out from the target 7, thereby forming the transparent electroconductive film (54 and 55) formed of the zinc oxide series material on the substrate 6.

In the film forming process, the concentration of hydrogen gas is five times or more the concentration of oxygen gas in the film formation chamber 3. Therefore, a reactive gas atmosphere in which a ratio of hydrogen gas to oxygen gas is well-balanced can be obtained. Accordingly, if sputtering is performed in the reactive gas atmosphere, the obtained transparent electroconductive film becomes a film having a desired electrical conductivity, with the number of oxygen vacancies in the zinc oxide crystals being controlled. Moreover, the specific resistance thereof decreases to become a desired specific resistance value. Furthermore, the obtained transparent electroconductive film maintains transparency with respect to visible light, without generating metallic luster.

Next, the substrate 6 is carried from the film formation chamber 3 to the load-unload chamber 2. Then, the vacuum state of the load-unload chamber 2 is broken, and the substrate 6 having the zinc oxide transparent electroconductive film formed thereon is taken out.

Thus, a substrate 6 (52 and 53) can be obtained, on which a zinc oxide transparent electroconductive film (54 and 55) having low specific resistance and excellent transparency with respect to visible light is formed. By using the substrate 6 (52 and 53) having the zinc oxide transparent electroconductive film (54 and 55) formed thereon for a liquid crystal display device, a pixel electrode having a low specific resistance and excellent transparency with respect to visible light can be formed. As a result, it is possible to produce a liquid crystal display device having high degree of transparency and excellent visibility with low power consumption, even with a zinc oxide transparent electroconductive film that can be produced at low cost.

The zinc oxide series material can be used as the transparent electroconductive film for only one of the pixel electrodes of the pixel electrodes (54 and 55) respectively formed on the pair of substrates (52 and 53) holding the liquid crystal layer therebetween, and the other pixel electrode can be formed of an ITO film or the like.

### EXAMPLES

Regarding the process for producing the liquid crystal display device of the present invention, experimental results of film forming of the zinc oxide transparent electroconductive film that forms the pixel electrode are outlined below.

### Example 1

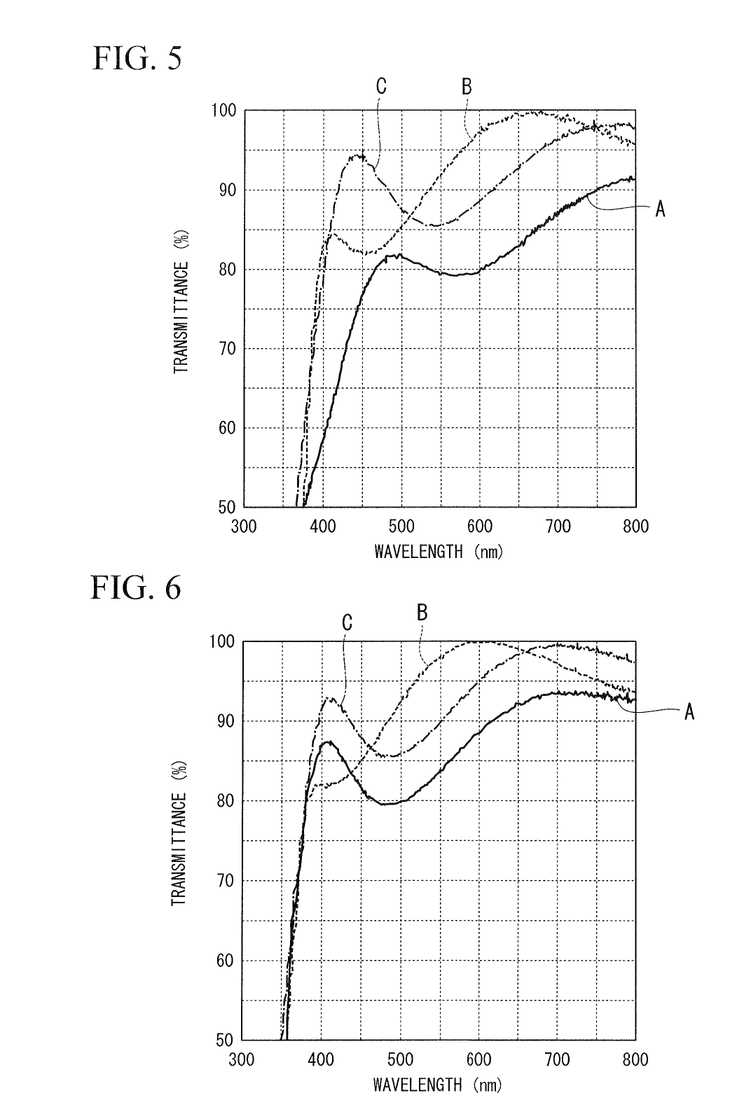

FIG. 5 is a graph showing an effect of H₂O gas (water vapor) in unheated film forming. In FIG. 5, A denotes the transmittance of the zinc oxide transparent electroconductive film when reactive gas was not introduced. In FIG. 5, B denotes the transmittance of the zinc oxide transparent electroconductive film when only H₂O gas was introduced so that the partial pressure of H₂O gas became 5×10⁻⁵ Torr. In FIG. 5, C denotes the transmittance of the zinc oxide transparent electroconductive film when only O₂ gas was introduced so that the partial pressure of O₂ gas became 1×10⁻⁵ Torr. As a cathode, a parallel plate-type cathode that applied a direct-current (DC) voltage was used.

When reactive gas was not introduced, the film thickness of the transparent electroconductive film was 207.9 nm and the specific resistance was 1576 μΩcm.

When only H₂O gas was introduced, the film thickness of the transparent electroconductive film was 204.0 nm and the specific resistance was 64464 μΩcm.

When only O₂ gas was introduced, the film thickness of the transparent electroconductive film was 208.5 nm and the specific resistance was 406 μΩcm.

According to the experimental results shown in FIG. 5, it was found that by introducing H₂O gas, the peak wavelength of the transmittance can be changed without changing the film thickness. Moreover, by introducing H₂O gas, the transmittance was also increased as a whole, as compared with A in which reactive gas was not introduced.

When H₂O gas is introduced, the specific resistance increases to increase resistance degradation. However, because the transmittance is high and the electrode area is large, it was found that it is suitable as a pixel electrode of a liquid crystal display device in which both low resistance and high transmittance are necessary.

Furthermore, it was found that by repeating film forming under a condition where; H₂O gas is not introduced, H₂O gas is introduced, or an introduction amount thereof is changed, a layered structure with a refractive index being changed can be obtained using one target.

### Example 2

FIG. 6 is a graph showing an effect of H₂O gas (water vapor) in heated film forming in which the substrate temperature was set to 250° C. In FIG. 6, A denotes the transmittance of the zinc oxide transparent electroconductive film when reactive gas was not introduced. In FIG. 6, B denotes the transmittance of the zinc oxide transparent electroconductive film when only H₂O gas was introduced so that the partial pressure of H₂O gas became 5×10⁻⁵ Torr. In FIG. 6, C denotes the transmittance of the zinc oxide transparent electroconductive film when only O₂ gas was introduced so that the partial pressure of O₂ gas became 1×10⁻⁵ Torr. As a cathode, a parallel plate-type cathode that applied a direct-current (DC) voltage was used.

When reactive gas was not introduced, the film thickness of the transparent electroconductive film was 201.6 nm and the specific resistance was 766 μΩ·cm.

When only H₂O gas was introduced, the film thickness of the transparent electroconductive film was 183.0 nm and the specific resistance was 6625 μΩ·cm.

When only O₂ gas was introduced, the film thickness of the transparent electroconductive film was 197.3 nm and the specific resistance was 2214 μΩ·cm.

According to the experimental results shown in FIG. 6, when only H₂O gas was introduced, the film thickness became slightly thinner. However, the peak wavelength shifted more than the shift of the peak wavelength due to interference of the film thickness. Accordingly, it was found that even when the substrate was heated to 250° C., the same effect as that of when the substrate was not heated could be obtained.

### Example 3

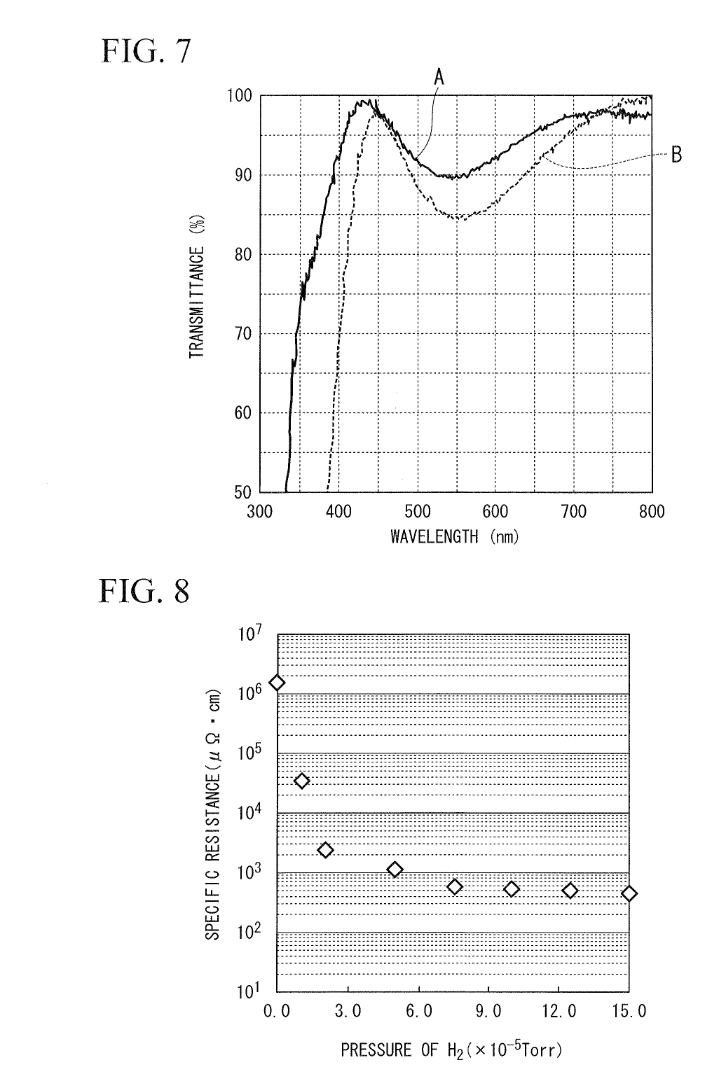

FIG. 7 is a graph showing an effect of H₂ gas and O₂ gas when these gases were introduced together, in heated film forming in which the substrate temperature was set to 250° C. In FIG. 7, A denotes the transmittance of the zinc oxide transparent electroconductive film when these gases were introduced, so that the partial pressure of H₂ gas became 15×10⁻⁵ Torr and the partial pressure of O₂ gas became 1×10⁻⁵ Torr. In FIG. 7, B denotes the transmittance of the zinc oxide transparent electroconductive film when only O₂ gas were introduced so that the partial pressure of O₂ gas became 1×10⁻⁵ Torr. As a cathode, a parallel plate-type cathode was used, in which a direct-current (DC) voltage and a high-frequency (RF) voltage could be superimposed.

When H₂ gas and O₂ gas were introduced at the same time, the film thickness of the transparent electroconductive film was 211.1 nm.

When only H₂O gas was introduced, the film thickness of the transparent electroconductive film was 208.9 nm

According to the experimental results shown in FIG. 7, it was found that when H₂ gas and O₂ gas were introduced at the same time, the peak wavelength shifted more than the shift of the peak wavelength due to interference of the film thickness, as compared with the case in which only O₂ gas was introduced. It was found that the transmittance was also improved.

### Example 4

FIG. 8 is a graph showing an effect of H₂ gas and O₂ gas when these gases were introduced together, in heated film forming in which the substrate temperature was set to 250° C. This shows the specific resistance of the zinc oxide transparent electroconductive film when the partial pressure of O₂ gas was fixed to 1×10⁻⁵ Torr (partial pressure converted to a flow rate) and the partial pressure of H₂ gas was changed in the range of 0 to 15×10⁻⁵ Torr (partial pressure converted to a flow rate). As the cathode, a parallel plate-type cathode was used, in which a direct-current (DC) voltage and a high-frequency (RF) voltage could be superimposed. The film thickness of the transparent electroconductive film was approximately 200 nm.

According to the experimental results shown in FIG. 8, the specific resistance abruptly decreased when the pressure of H₂ gas was from 0 Torr to 2.0 Torr. On the other hand, it was found that when the pressure of H₂ gas exceeded 2.0 Torr, the specific resistance was stabilized. The specific resistance of the transparent electroconductive film when reactive gas was not introduced under the same conditions was 422 μΩcm. Accordingly, it was found that degradation of the specific resistance was small, even when H₂ gas and O₂ gas were introduced at the same time.

Particularly, as a pixel electrode of the liquid crystal display device, it is required that the transmittance in the visible light range is high and the electrode has low resistance in order to increase the visibility of the liquid crystal layer. A general pixel electrode needs to have a specific resistance of 1000 μΩ·cm or less. In FIG. 8 where the specific resistance becomes 1000 μΩ·cm or less, is when the pressure of H₂ gas is 5.0×10⁻⁵ Torr or more. Because the pressure of O₂ gas is 1×10⁻⁵ Torr, it is seen that the ratio R is preferably R=P_{H2}/P_{O2}≧5 in order to obtain the specific resistance of 1000 μΩcm or less.

### Example 5

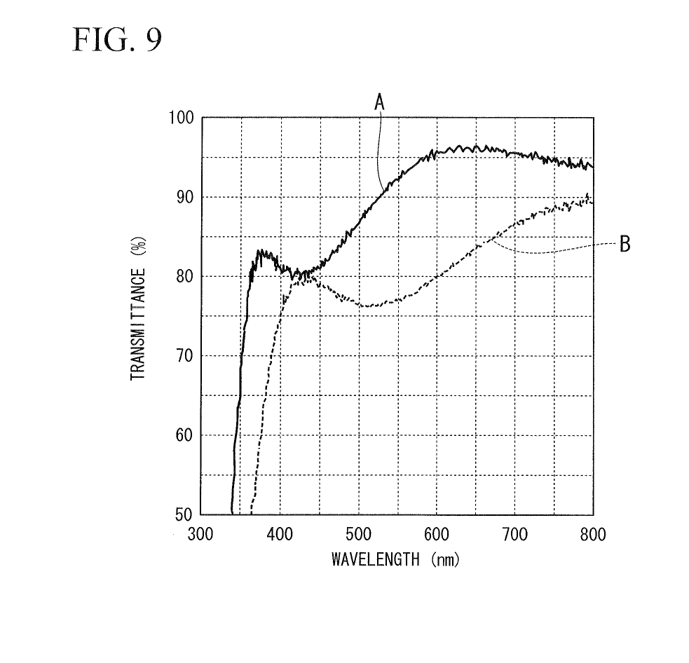

FIG. 9 is a graph showing an effect of H₂ gas in unheated film forming. In FIG. 9, A denotes the transmittance of the zinc oxide transparent electroconductive film when only H₂ gas was introduced so that the partial pressure of H₂ gas became 3×10⁻⁵ Torr. In FIG. 9, B denotes the transmittance of the zinc oxide transparent electroconductive film when only O₂ gas was introduced so that the partial pressure of O₂ gas became 125×10⁻⁵ Torr. As a cathode, an opposed cathode that applied a direct-current (DC) voltage was used.

When only H₂ gas was introduced, the film thickness of the transparent electroconductive film was 191.5 nm and the specific resistance was 913 μΩcm.

When only O₂ gas was introduced, the film thickness of the transparent electroconductive film was 206.4 nm and the specific resistance was 3608 μΩcm.

According to the experimental results shown in FIG. 9, it was found that by introducing only H₂ gas, the peak wavelength of the transmittance could be changed without changing the film thickness. It was also found that the transmittance was higher than the case in which only O₂ gas was introduced. Accordingly, it was found that the process of introducing only H₂ gas could obtain a zinc oxide transparent electroconductive film having a high transmittance and low specific resistance, by optimizing the introduction amount of H₂ gas.

According to the experimental results, particularly, when it is desired to change the peak wavelength of the transmittance, the shift amount of the peak can be largely changed by introducing water vapor. The shift amount can also be adjusted by introducing hydrogen or oxygen.

Particularly, when it is desired to make both transmittance and low resistance compatible at a high level, it is preferable to introduce oxygen and hydrogen.

That is to say, according to the process for producing the liquid crystal display device of the present invention, the transmittance and low resistance can be realized at a high level and the peak wavelength of the transmittance and the shift amount of the peak can be adjusted by appropriately setting the type and pressure of the sputtering gas.

Comparison of transmittance

### Example 6

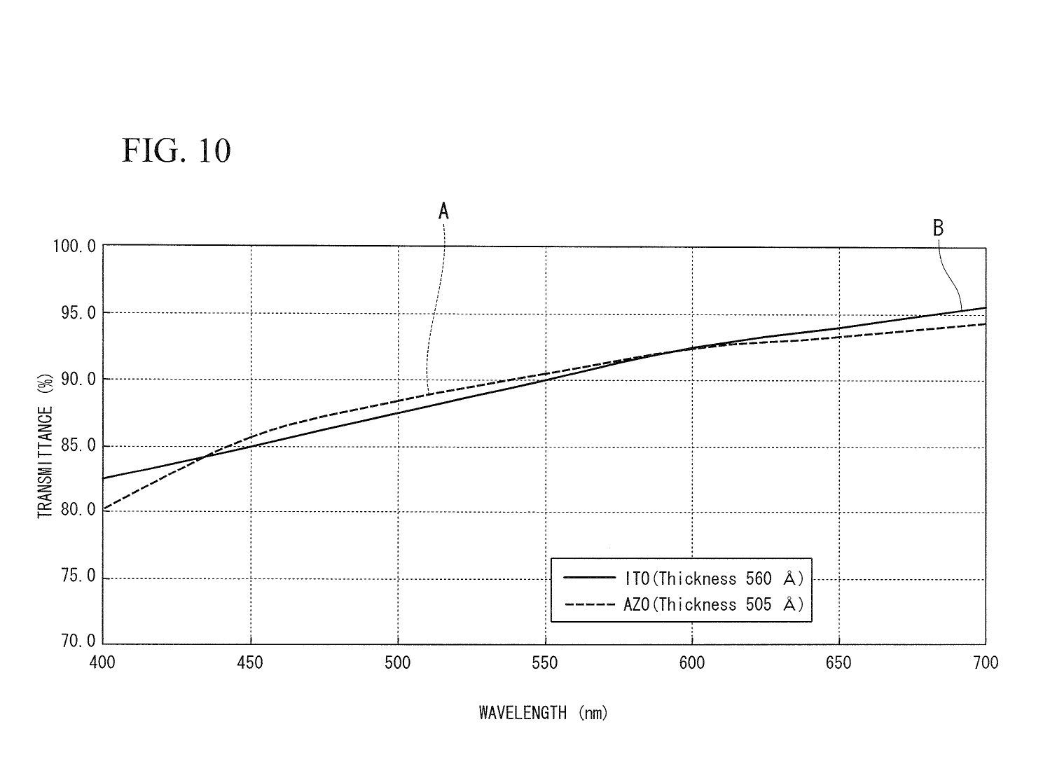

FIG. 10 is a graph showing the measurement results of the transmittance of light in the wavelength range of 400 to 700 nm by using a substrate on which an ITO film was formed, and a substrate in Example 6 on which an AZO (aluminum doped zinc oxide) film was formed under the same conditions as in Example 1. In FIG. 10, A denotes the transmittance of the substrate in Example 6 on which the AZO film was formed at a thickness of 50.5 nm In FIG. 10, B denotes the transmittance of the substrate on which the ITO film was formed at a thickness of 56.0 nm

According to the experimental results shown in FIG. 10, it was confirmed that, in the wavelength range of 400 to 700 nm, the transmittance of the substrate on which a conventional ITO film was formed, and the transmittance of the substrate on which the AZO film was formed according to the process for producing the liquid crystal display device of the present invention, are almost the same.

### Example 7

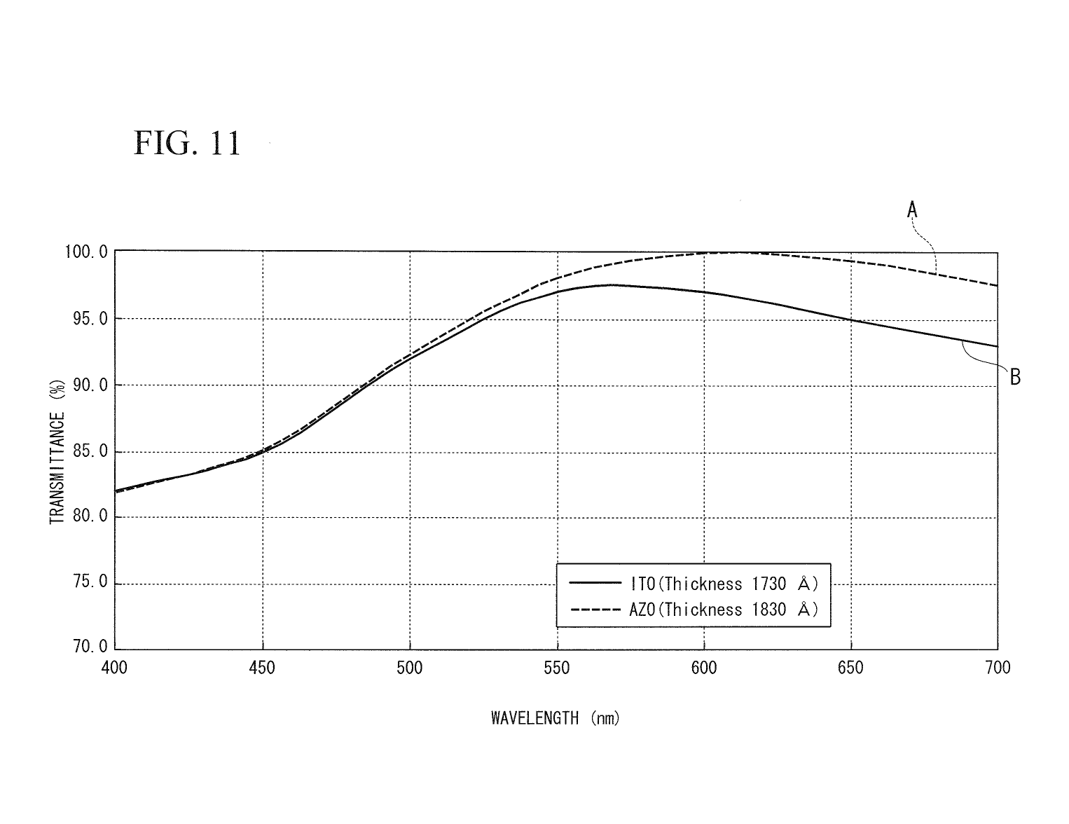

FIG. 11 is a graph showing the measurement results of the transmittance of light in the wavelength range of 400 to 700 nm by using a substrate on which an ITO film was formed, and a substrate in Example 7 on which an AZO (aluminum doped zinc oxide) film was formed under the same conditions as in Example 1. In FIG. 11, A denotes the transmittance of the substrate in Example 7 on which the AZO film was formed at a thickness of 183.0 nm In FIG. 11, B denotes the transmittance of the substrate on which the ITO film was formed at a thickness of 173.0 nm

According to the experimental results shown in FIG. 11, it was confirmed that in the wavelength range of 400 to 500 nm, the transmittance of the substrate on which a conventional ITO film was formed, and the transmittance of the substrate on which the AZO film was formed according to the present invention, are almost the same. On the other hand, in the wavelength range of 500 to 700 nm, it was found that the substrate on which the AZO film was formed according to the production process of the present invention has more excellent transmittance than the substrate on which the conventional ITO film was formed.

Table 1 shows the results of a comprehensive evaluation of transparent electroconductive films of ITO (comparative example in which tin oxide was doped), AZO formed under the same conditions as Example 1 (example of the present invention in which aluminum oxide was doped), and ATO (comparative example in which antimony oxide was doped) for; average resistance value, etching characteristics, light transmittance, and material cost, in three levels (excellent, good, and pass).

TABLE 1

| | | Etching | | |
|---|---|---|---|---|
| | Resistance | character- | Transmittance | Material |
| | (μΩ/cm) | istics | (%) | cost |
| ITO (In₂O₃•SnO₂) | 2 × 10² | excellent | good | pass |
| AZO (ZnO•Al₂O₂) | 1 × 10³ | good | excellent | excellent |
| ATO (SnO₂•Sb₂O₃) | 3 × 10³ | pass | good | good |

According to the result shown in Table 1, it was confirmed that the AZO film formed according to the example of the production process of the present invention is superior to the ITO and ATO films in the Comparative Examples in all of; average resistance value, etching characteristics, transmittance of light, and material cost. Particularly, in the material cost, by using zinc oxide, the cost can be considerably reduced compared to the case of using the ITO film, which has conventionally been generally used as the transparent electroconductive film. It was also found that the transmittance and low resistance, which are important for the pixel electrode of the liquid crystal display device, can be obtained at a highly competitive level, and usability of the present invention was confirmed.

### INDUSTRIAL APPLICABILITY

In the process for producing the liquid crystal display device of the present invention, when a zinc oxide transparent electroconductive film that forms a pixel electrode of the liquid crystal display device is formed by sputtering, sputtering is performed in an atmosphere containing two or three materials selected from the group consisting of hydrogen gas, oxygen gas, and water vapor. Therefore, the atmosphere at the time of forming the zinc oxide transparent electroconductive film can be an atmosphere including two or three materials selected from the group consisting of hydrogen gas, oxygen gas, and water vapor, that is, an atmosphere in which the ratio of reducing gas to oxidizing gas is well-balanced. Accordingly, if sputtering is performed in this atmosphere, the obtained transparent electroconductive film becomes a film having a desired electrical conductivity, with the number of oxygen vacancies in the zinc oxide crystals being controlled. Therefore, surface resistance thereof also decreases to give a desired surface resistance value.

What is claimed is:

1. A process for producing a liquid crystal display device that comprises at least a pair of substrates holding a liquid crystal layer therebetween and a pixel electrode superimposed on the liquid crystal layer side of the pair of substrates, the pixel electrode on at least one of the pair of substrates being formed of a transparent electroconductive film made of zinc oxide as a fundamental constituent material, the process comprising:
a step of forming a zinc oxide transparent electroconductive film on the substrate by sputtering, using a target of a zinc oxide series material to form the pixel electrode, wherein
in the step of forming the pixel electrode, sputtering is performed in an atmosphere containing two or three materials selected from the group consisting of hydrogen gas, oxygen gas, and water vapour, a ratio R of a partial pressure P_{H2} of hydrogen gas to a partial pressure P_{O2} of oxygen gas satisfies:
R=P_{H2}/P_{O2}≧5.

2. (canceled)

3. The process for producing a liquid crystal display device according to claim 1, wherein a sputtering voltage is less than or equal to 340V.

4. The process for producing a liquid crystal display device according to claim 1, wherein in the sputtering voltage, a high-frequency voltage is superimposed on a direct-current voltage.

5. The process for producing a liquid crystal display device according to claim 1, wherein a maximum value of the intensity of a horizontal magnetic field on a surface of the target is greater than or equal to 600 gauss.

6. The process for producing a liquid crystal display device according to claim 1, wherein the liquid crystal display device further includes a color filter between the liquid crystal layer and the substrate, and the pixel electrode is formed between the color filter and the liquid crystal layer.

7. The process for producing a liquid crystal display device according to claim 1, wherein the zinc oxide series material is aluminum doped zinc oxide or gallium doped zinc oxide.
